(19) United States
(12) Patent Application Publication
(10) Pub. No.: US 2017/0186711 A1
(43) Pub. Date: Jun. 29, 2017

(54) STRUCTURE AND METHOD OF FAN-OUT STACKED PACKAGES

(71) Applicant: POWERTECH TECHNOLOGY INC., Hsinchu (TW)

(72) Inventors: Li-Chih FANG, Hsinchu (TW); Chia-Wei CHANG, Hsinchu (TW); Kuo-Ting LIN, Hsinchu (TW)

(21) Appl. No.: 15/378,898

(22) Filed: Dec. 14, 2016

(30) Foreign Application Priority Data
Dec. 23, 2015 (TW) 104143308

(51) Int. Cl. H01L 23/00; H01L 21/56; H01L 21/78; H01L 25/00; H01L 25/065; H01L 23/31

(52) U.S. Cl. CPC H01L 24/02; H01L 25/0657; H01L 23/3114; H01L 21/78; H01L 25/50; H01L 21/565; H01L 2224/02331; H01L 2224/02371; H01L 2224/02379; H01L 2224/02373

(57) ABSTRACT

A fan-out stacked packages are formed by stacking a plurality of tiers followed by singulation process. Each tier comprises a plurality of units. Each unit comprises at least one chip, an encapsulation encapsulating the at least one chip, and a redistribution layer. The redistribution layer is electrically connected to the bond pads of the chip. A dielectric layer is formed on the redistribution layer. Adhesive pads are used to attach the plurality of tiers to each other. The redistribution layers of the units have a plurality of trace breakpoints electrically connected to each other using lateral traces formed on the sidewalls of the units.

### FIELD OF THE INVENTION

The present invention relates to a semiconductor package and more specifically to a structure and a method of fan-out stacked packages.

### BACKGROUND OF THE INVENTION

Stacking of a plurality of semiconductor chips has been implemented in various semiconductor packages to achieve miniaturization of component integration where Through Silicon Via (TSV) has been implemented for micro electrical interconnection among bond pads of the stacked chips. However, Through Silicon Via will increase stacked heights and processing complexity leading to larger package thickness and lower manufacturing yield with higher packaging cost.

Another electrical interconnection among the stacked chips is to implement Through Mold Via to align with and join to the fan-out circuitry, i.e., manufacturing Through Mold Via in tier, disposing solder balls, solder paste, or bumps between the tiers to electrically connect adjacent tiers. Therefore, the requirements for the precision of alignment and locating among the micro contact points are very high. When the dimension of the laminated substrates becomes larger and larger, the position shift of the micro contact points becomes greater and greater leading to poor packaging yield. Moreover, each substrate lamination process will proceed thermal compression for the joints of the micro contact points where the more the stacked chips, the more the risk of breaking the joints of the micro contact points. Thus, the larger the laminated substrate, the more the number of thermal compression on the same substrate, the packaging yield and the package reliability become a great challenge.

### SUMMARY OF THE INVENTION

The main purpose of the present invention is to provide a structure and a method of fan-out stacked packages to greatly reduce the thickness of the structure.

The second purpose of the present invention is to provide a structure and a method of fan-out stacked packages to increase the tolerance errors at the scribe lines bias and to enforce the protection of the sidewalls of the chips to further shrink the dimension of the chips so that the effective IC area of the chip active surface is further increased.

The third purpose of the present invention is to provide a structure and a method of fan-out stacked packages to replace the structures and processes of Through Silicon Via and Through Mold Via to improve the advanced packaging yield and to reduce the packaging cost.

According to the present invention, a structure of fan-out stacked packages is disclosed, which is manufactured by 3D stacking processes of the packaged slices and singulation cutting processes. The fan-out stacked package comprises a plurality of chips, a plurality of encapsulated dice, a plurality of redistribution layers, a plurality of dielectric layers, and at least an adhesive pad unit. The chips are vertically arranged. A plurality of bond pads are disposed on an active surface of each chip. The encapsulations encapsulate the chips in the corresponding tier where each encapsulation has an inner surface. The redistribution layers are formed on the corresponding inner surface of the encapsulated die. Each redistribution layer electrically connects to the corresponding bond pads of each chip. The dielectric layers are formed on the corresponding inner surface of the encapsulation to encapsulate the redistribution layers. The adhesive pad is formed between the adjacent encapsulation dice. The adhesive pad is pre-formed on one of the corresponding dielectric layer unit of encapsulation to adhere an outer surface of the adjacent encapsulated dice. Moreover, the structure of the fan-out stacked packages has a plurality of cut sidewalls where the redistribution layers have a plurality of trace breakpoints exposed from the cut sidewalls. Furthermore, the structure of the fan-out stacked packages further has a plurality of lateral traces formed on the cut sidewalls to connect to the trace breakpoints. The manufacturing method of the structure of the fan-out stacked packages is also revealed in the present invention.

### DESCRIPTION OF THE DRAWINGS

FIG. 1 is a cross-sectional view of a structure of the fan-out stacked package according to the first embodiment of the present invention.

FIGS. 2A to 2J are cross-sectional views of a structure of the fan-out stacked package of FIG. 1 during packaging process.

FIG. 3 is a three-dimensional view of a structure of the fan-out stacked package of FIG. 1.

FIG. 4 is a cross-sectional view illustrating a structure of the fan-out stacked package according to the second embodiment of the present invention during a step in a packaging process.

FIG. 5 is a cross-sectional view illustrating the structure of the fan-out stacked package of FIG. 4 during another step in the packaging process.

FIG. 6 is a three-dimensional view of a structure of the fan-out stacked package of FIG. 4.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

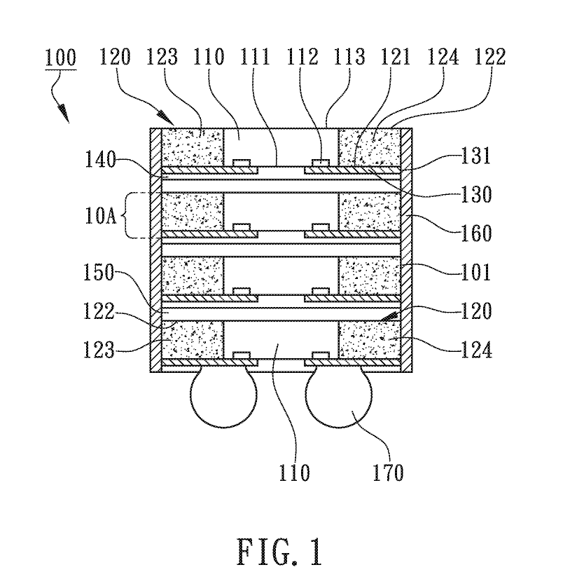

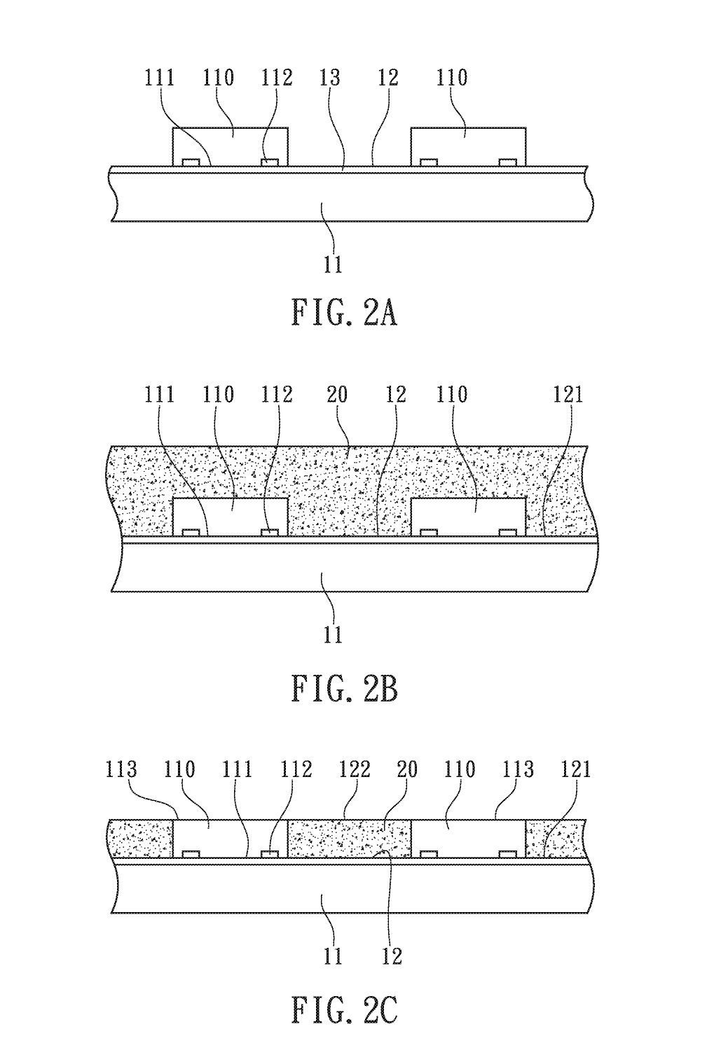

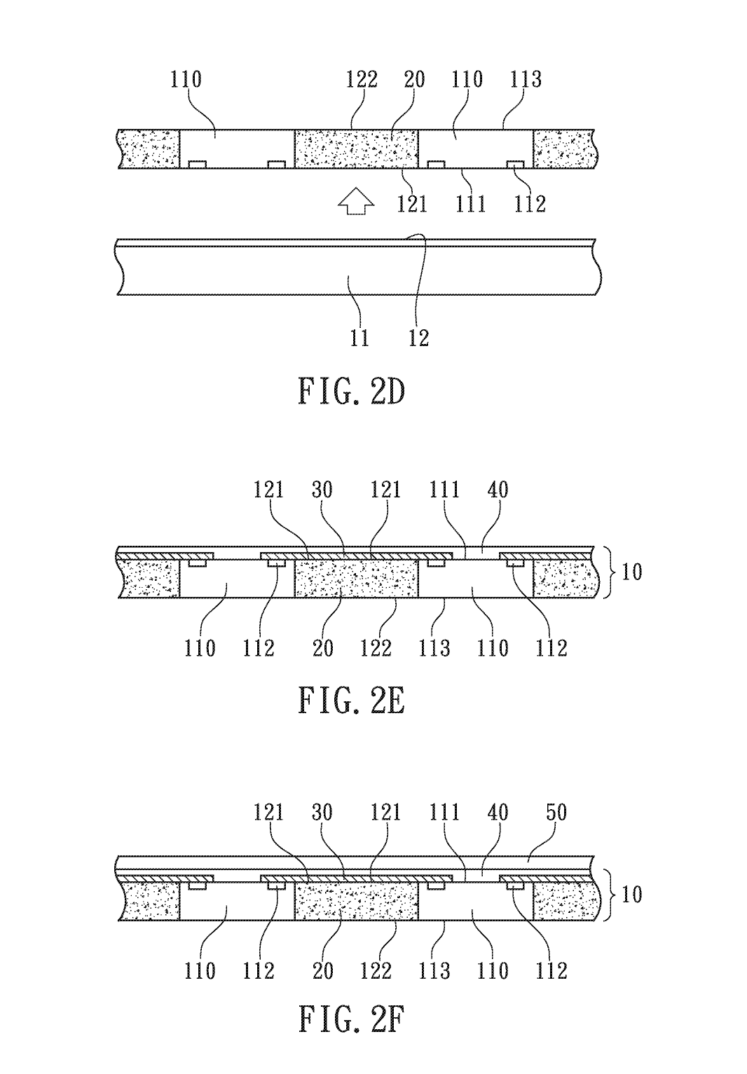

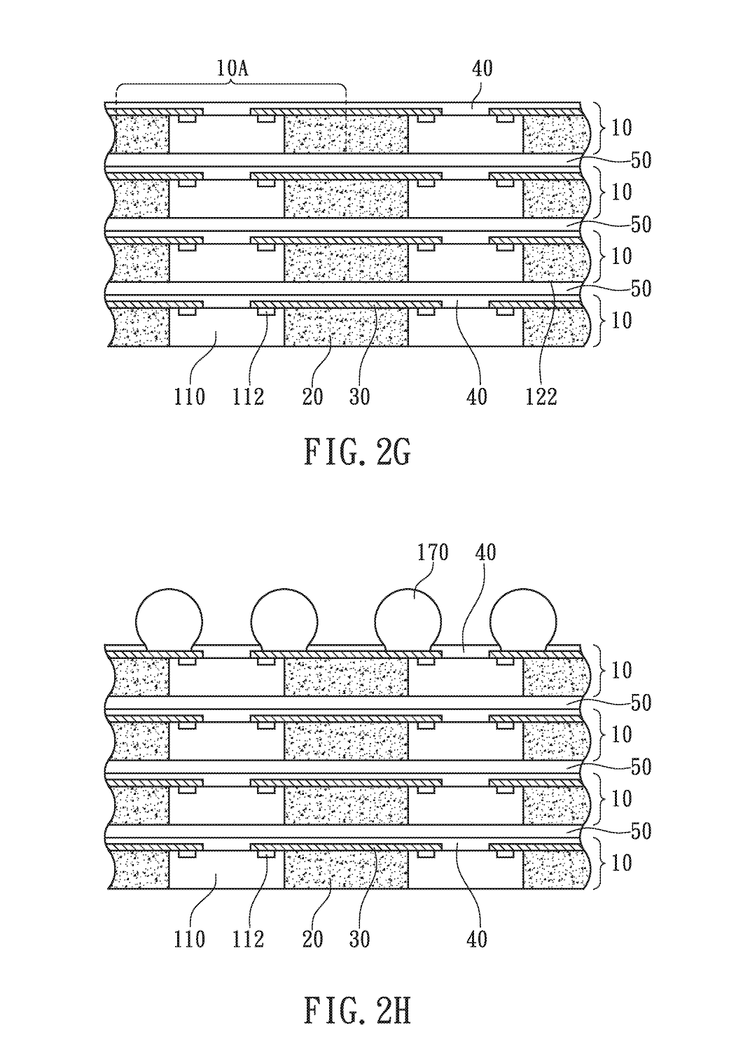

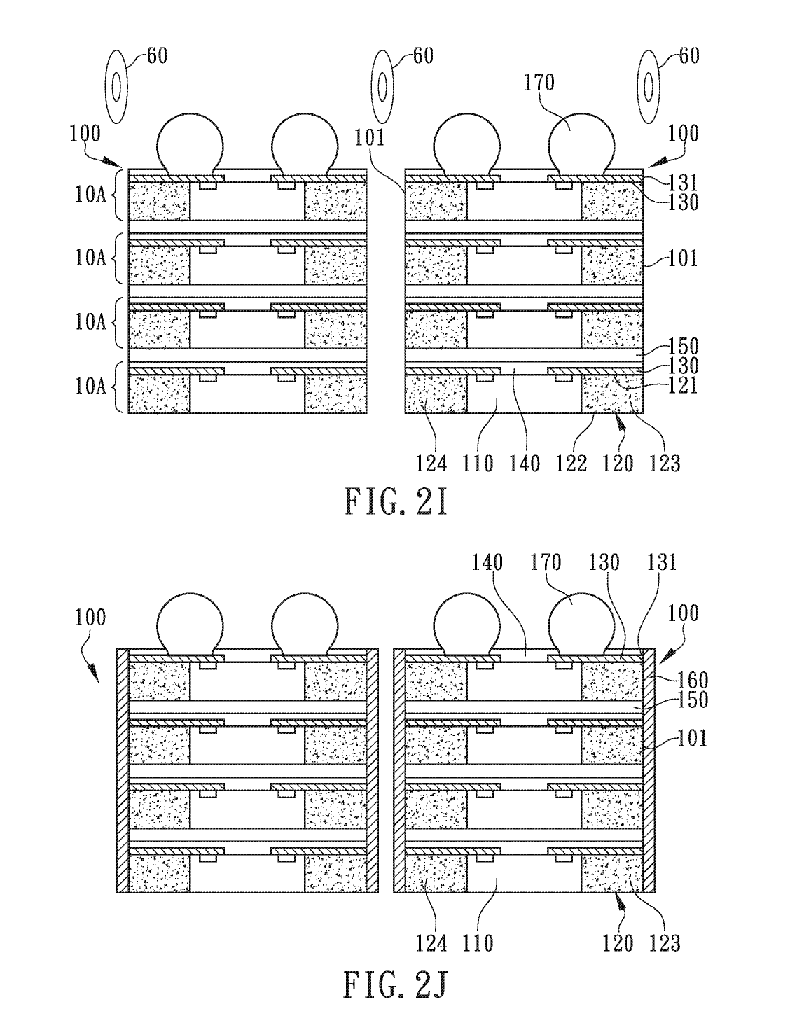

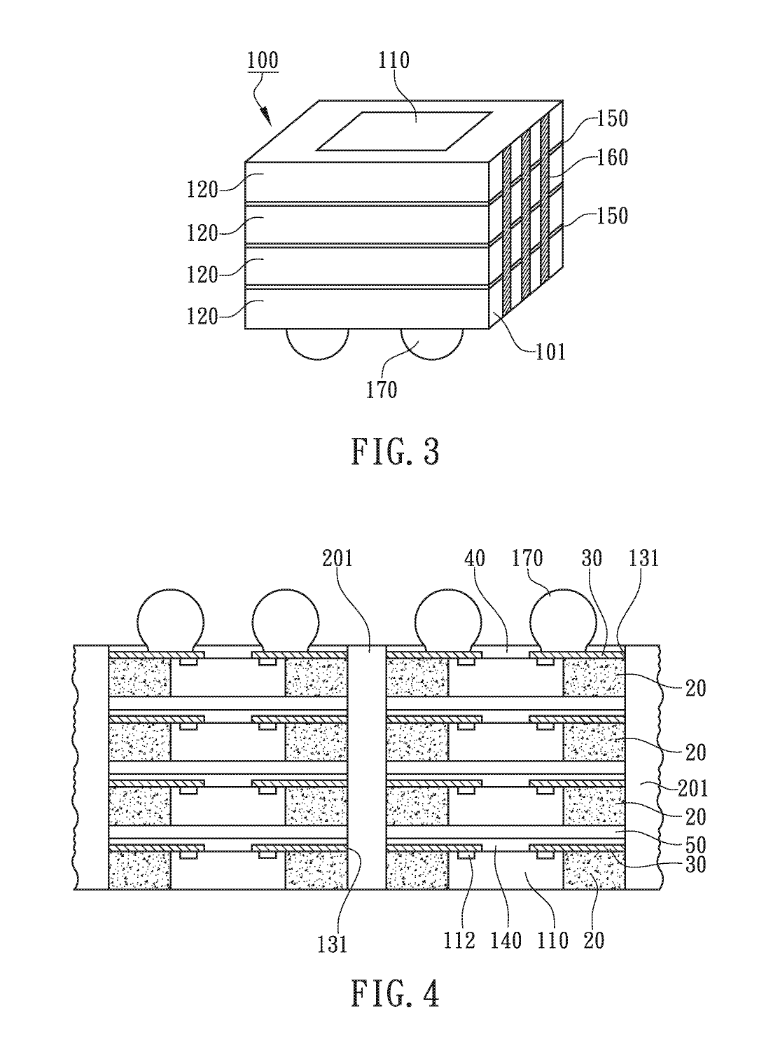

According to the first embodiment of the present invention, a cross-sectional view of a structure of the fan-out stacked package 100 is illustrated in FIG. 1. FIG. 2A to FIG. 2J illustrates cross-sectional views of a structure of the fan-out stacked package 100 during the packaging process. FIG. 3 illustrates a three-dimensional view of the fan-out stacked package 100. The structure of the fan-out stacked package 100 comprises a plurality of units 10A from different tiers 10 as shown in FIG. 2E stacked on top of each other. A singulation process is then performed on the plurality of tiers 10 as shown in FIG. 2I. The structure of the fan-out stacked package 100 comprises a plurality of units 10A. Each of the unit 10A may have at least one chip 110, an encapsulation 120, a redistribution layer 130 and a dielectric layer 140. The units 10A may be attached to each other using an adhesive pad 150. The units 10A stacked on top of each other may be identical or different from each other.

Each chip 110 has an active surface 111 with at least one bond pad 112 disposed on the active surface 111. The bond pads 112 are used as external terminals of the integrated circuit within the chip 110. The bond pads 112 may be Aluminum pads, Copper pads, or UBM composite pads. The bond pads 112 may be disposed on the peripheral of the active surface 111. The chips 110 are stacked with the active surfaces 111 facing the temporary carrier 11 to reduce the thickness of the stacked package 100. The chips 110 may be formed on semiconductor materials such as silicon wafer and the integrated circuit of the chips 110 are formed on the active surfaces of the silicon wafer.

As shown in FIG. 1, the encapsulation 120 of each unit may encapsulate the chip 110. Each encapsulation 120 has an inner surface 121 and an outer surface 122. The encapsulations 120 may be molding isolation materials used to at least encapsulate the sidewalls of the chips 110. The inner surface 121 of the encapsulation 120 may be coplanar to the active surface 111 of the chip 110 and the outer surface of the encapsulation 120 may be coplanar to the back surface 113 of the chip 110. In this way, the thickness of the encapsulation 120 is substantially equal to the thickness of the chip 110. Thus, the total thickness of stacked package 100 may be greatly reduced. The back surface of the chip 110 at the top of the stacked package 100 may be exposed through the encapsulation 120 to improve the heat dissipation.

As shown in FIG. 1, the redistribution layer 130 is formed on the inner surface 121 of the encapsulation 120. Each redistribution layer 130 is electrically connected to the bond pads 112 of the chip 110. The redistribution layers 130 comprise a fan-out circuit and a planar circuit. The fan-out circuit is formed on the active surface 111 of the chip 110 to couple to the bond pads 112 and extends towards the inner surface 121 of the encapsulation 120 and the planar circuit is formed on the inner surface 121 of the encapsulation 120.

An encapsulation 120 comprises a plurality of mold sides 123, 134 to encapsulate the sidewalls of the chip 110. The structure of the fan-out stacked package 100 may allow the larger displacement errors for singulation cutting without affecting the electrical connection between the redistribution layers 130 of the units 10A.

The redistribution layer 130 may outwardly extend from the mold sides 123, 124 and may end at the trace breakpoints 131 coplanar to the sidewalls of the encapsulation 120. The redistribution layers 130 are in fan-out type. The materials used to form the redistribution layers 130 are conductive metals such as Copper or other appropriate metals. The redistribution layers 130 are formed using sputtering, patterned etching, patterned electrical plating or lift-off process.

The dielectric layer 140 is formed on the inner surface 121 of the encapsulation 120 to cover the redistribution layer 130 and prevent circuit exposure, contamination, and electrical short. The materials used to form the dielectric layer 140 may be a Polyimide (PI) or other organic isolation-protection materials. The dielectric layer 140 may further be disposed on the active surfaces 111 of the chip 110.

As shown in FIG. 1, the adhesive pad 150 is formed between adjacent units 10A. The adhesive pad 150 may be formed on the dielectric layer 140 of an encapsulation 120 to adhere the outer surface 122 of the encapsulation 120 of an adjacent unit 10A. The adhesive pad 150 may function as an adhesive between the units 10A.

Furthermore, the structure of the fan-out stacked package 100 has a plurality of sidewalls 101. The redistribution layer 130 has a plurality of trace breakpoints 131 exposed from the sidewall 101 of the unit 10A. The sidewall 101 may further expose the sidewalls of the encapsulations 120, the trace breakpoints 131 of the redistribution layers 130, the sidewalls of the dielectric layer 140, and the sidewalls of the adhesive pad 150. The structure of the fan-out stacked package 100 further comprises a plurality of lateral traces 160 formed on the cut sidewalls 101 to couple to the trace breakpoints 131 to each other.

As shown in FIG. 1, the structure of the fan-out stacked package 100 further comprises a plurality of external terminals 170 disposed on the dielectric layer 140 exposed on the fan-out stacked package 100. The external terminals 170 may be a plurality of solder balls, solder pastes, contact pads, or contact pins. the external terminals 170 may be a plurality of solder balls used to form a multi-chip Ball Grid Array package. In this way, the chips 110 disposed inside the structure of the fan-out stacked package 100 may be able to electrically connect to an external Printed Circuit Board (PCB). The external terminals 170 may accommodate more I/O connection on the same unit area of the semiconductor chip carrier to meet the requirements of the high-integrated semiconductor chip packages.

The manufacturing method of the fan-out stacked package 100 is illustrated in FIG. 2A to FIG. 2J.

The method of forming the plurality of tiers 10 are illustrated from FIG. 2A to FIG. 2F. The method of forming each tier 10 comprises the following steps:

As shown in FIG. 2A, a plurality of chips 110 are disposed on a carrier plane 12 of a temporary carrier 11. A plurality of bond pads 112 are disposed on the active surfaces 111 of each chip 110. The temporary carrier 11 may be a glass carrier or a semiconductor carrier in wafer type or in panel type. For example, the temporary carrier 11 is a 12 inch glass wafer carrier. A temporary adhesive layer 13 may be disposed on the carrier plane 12. The carrier plane 12 may have adhesive property to adhere the chips 110 on the temporary carrier 11. The chips 110 may be disposed on the carrier plane 12 with the active surface 111 facing towards the temporary carrier 11.

As shown in FIG. 2B, an encapsulant 20 is formed on the carrier plane 12 using molding process to encapsulate the chips 110. The encapsulant 20 may provide packaging protection to the chips 110 to avoid electrical short and contamination. An inner surface 121 of the encapsulant 20 is formed on the carrier plane 12. The inner surface 121 may be coplanar to the active surfaces 111 of the chips 110. The encapsulant 20 may be an Epoxy Molding Compound (EMC) formed by transfer molding or by die molding. The encapsulant 20 may also be formed by injection molding process such as compression molding.

As shown in FIG. 2C, a planarization grinding step is performed to grind the encapsulant 20 until back surfaces 113 of the chips 110 are exposed. The outer surface 122 of the encapsulant 20 formed by a plurality of encapsulations 120 is coplanar to the back surfaces 113 of the chips 110.

As shown in FIG. 2D, the encapsulant 20 and the chips 110 are decoupled from the temporary carrier 11 to expose the inner surface 121 of the encapsulant 20 and active surfaces 111 of the chips 110. The thickness of the encpasulant 20 may be equivalent to the thickness of the chips 110. The sidewalls of the chips 110 are encapsulated by the encapsulant 20.

As shown in FIG. 2E, a redistribution layer 30 is formed on the inner surface 121 of the encapsulant 20. The redistribution layer 30 is electrically connected to the corresponding bond pads 112. The redistribution layer 30 is further formed on the active surfaces 111 of the chips 110. The redistribution layer 30 may be a circuitry formed by conductive metals. In some embodiments, the redistribution layer 30 may be a multi-layer metal stack such as Titanium (Ti)/Copper (Cu)/Copper (Cu) or Titanium (Ti)/Copper (Cu)/Copper (Cu)/Nickel (Ni)/gold (Au). When forming the redistribution layer 30, the part of the redistribution layer 30 are to be cut to form the trace breakpoints 131 may be formed along the scribe line of the tier 10. In some embodiment the redistribution layer 30 of two adjacent units 10A may be coupled to each other. In some other embodiment, the redistribution layer 30 of a unit 10A may be formed across scribe line having part of the redistribution layer 30 of the unit 10A be formed on the inner surface of another unit 10A. The redistribution layer 30 may replace the conventional structure and processes of Through Silicon Via and Through Mold Via to further improve the packaging yield and to reduce the manufacturing cost.

As shown in FIG. 2E, a dielectric layer 40 is formed on the inner surface 121 of the encapsulant 20 by deposition process or spin coating process to cover the redistribution layer 30 to compose individual tier 10. The dielectric layer 40 further covers the active surfaces 111 of the chips 110. The dielectric layer 40 encapsulates and isolates the redistribution layer 30 from moisture or external contamination. The dielectric layer 40 may be a polyimide.

As shown in FIG. 2F, an adhesive pad 50 is formed on the dielectric layers 40 of the tiers 10. The adhesive pad 50 is used during the stacking of the tiers 10. The adhesive pad 50 may be, but not limited to, a Die Attach Film (DAF). The adhesive pad 50 may also be a heat-conductive adhesive layer.

As shown in FIG. 2G the tiers 10 are 3D stacked wherein the adhesive pads 50 are formed between the adjacent tiers 10. The adhesive pads 50 may be pre-formed on the dielectric layers 40 of the corresponding tiers 10, moreover, the adhesive pads 50 adhere the outer surface 122 of the encapsulant 20 adjacent to the tiers 10.

As shown in FIG. 2H, after stacking the tiers 10, a plurality of external terminals 170 may be disposed on the outermost dielectric layer 40. The external terminals 170 may be provided to form external connection for fan-out stacked package 100.

As shown in FIG. 2H and FIG. 2I, the tiers 10 are singulated to form a plurality of fan-out stacked packages 100. The singulation process may use a laser cutter or a blade cutter 60 to cut through the encapsulant 20 through the pre-defined scribes lines. Each fan-out stacked package 100 comprises a plurality of vertically stacked chips 110, a plurality of encapsulations 120 encapsulating the chips 110, a plurality of redistribution layers 130 formed on the inner surfaces 121 of the encapsulations 120, a plurality of dielectric layer 140 covering the redistribution layers 130, and at least an adhesive pad 150 disposed between adjacent encapsulations 120. Each fan-out stacked package 100 has a plurality of sidewalls 101. The redistribution layers 130 have a plurality of trace breakpoints 131 exposed through the sidewalls 101. After the singulation process, the trace breakpoints 131 of the redistribution layers 130 are exposed from the sidewalls 101. The surfaces of the trace breakpoints 131 can be seen from the surface view of the sidewalls 101.

After the singulation, the mold side 123, 124 of the encapsulation 120 may have widths that are equal or different from each other. In embodiments where conductive pillars or passive components are needed, the width of the mold side where conductive pillars or passive components are to be implemented may have greater width compared to the width of the other mold sides. In some other embodiments, the widths of the mold sides may vary depending on the dimension required by the final packaging.

As shown in FIG. 2J and FIG. 3, a plurality of lateral traces 160 are formed on the sidewalls 101 to electrically connect to the trace breakpoints 131. The lateral traces 160 may be formed formed by dispensing liquid conductive paste of the sidewalls 101. The lateral traces 160 may be formed through 3D printing or 3D dispensing process. The lateral traces 160 are dispensed and extends through the trace breakpoints 131 to connect the trace breakpoints 131 disposed in the same row.

Therefore, the fan-out stacked package and method disclosed in the present invention reduces the package thickness by increasing the margin of error for the scribe line during singulation process and by increasing the protection of the sidewalls of the chips. Thus, the size of the chip may be reduced and the proportion of the effective integrated circuit on the active surface of the chip may be increased. Furthermore, the conventional structures and processes of Through Silicon Via and Through Mold Via may be replaced to further improve the packaging yield and reduce the manufacture cost.

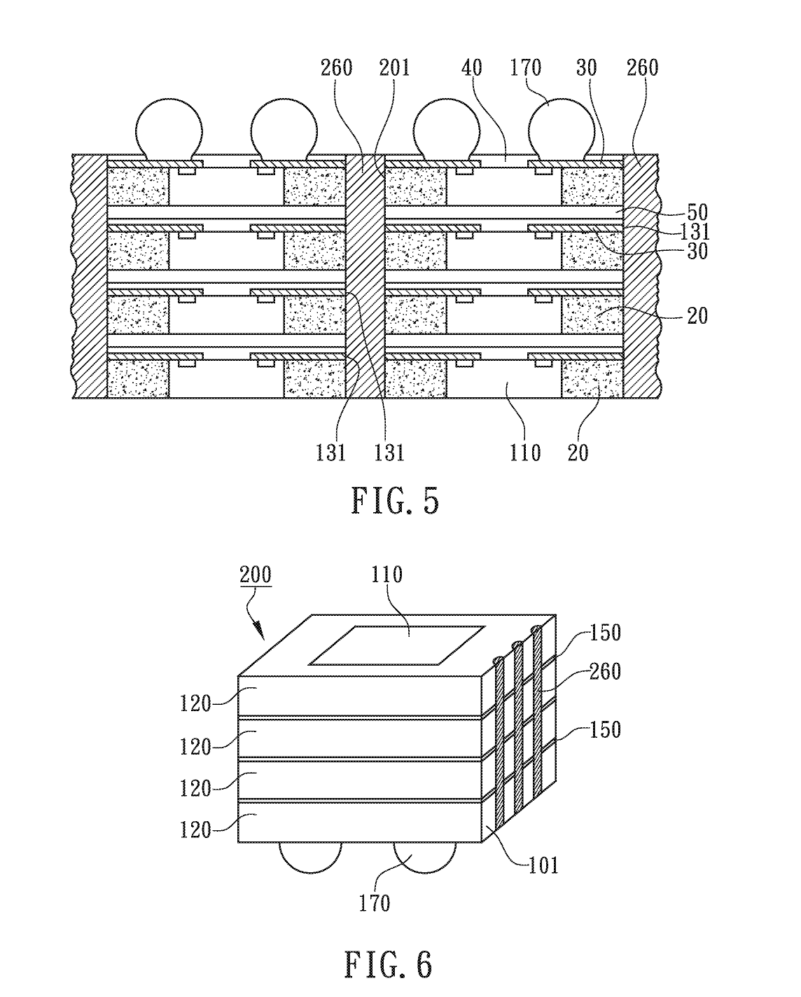

According to the second embodiment of the present invention, a cross-sectional view of another fan-out stacked package during the via opening step to dispose the lateral trace on the cut sidewalls is illustrated in FIG. 4. FIG. 5 illustrates a cross-sectional view of the fan-out stacked package during the via filling step to dispose the lateral trace on the cut sidewalls. FIG. 6 is a three-dimensional view of a structure of the fan-out stacked package of FIG. 4. The components with the same names and functions as in the first embodiment will be followed without further detail description. The second embodiment has the same manufacture method as the first embodiment having the packaging process illustrated in FIG. 2A to FIG. 2H. The only difference is the sequence of the formation of the lateral trace.

As shown in FIG. 4, after 3D stacking the tiers 10, a plurality of through holes 201 are formed by laser drilling, mechanical drilling, reactive ion etching (RIE), or lithography combined with chemical etching or plasma etching to penetrate through the encapsulant 20. In this way, the redistribution layers 30 may have a plurality of trace breakpoints 131 exposed from the through holes 201. As shown in FIG. 5, a plurality of lateral traces 260 are formed inside the through holes 201 utilizing compression, filling, or electrical plating to electrically connect the trace breakpoints 131 of the redistribution layers 30. The singulation process may be performed after the plurality of lateral traces 260 are formed on the tiers 10.

The lateral traces 260 may be metal layers formed in through-holes of the tiers 10 by electrical plating or conductive materials formed in through-holes of the tiers 10 by filling process. Conductive materials may be sintering metal, conductive paste such as silver paste or copper paste used in liquid printing , solder paste such as Sn-Pb or lead-free solder paste, copper pillars formed by electroplating, conductive printing ink, etc. The lateral traces 260 are electrically connected with the trace breakpoints 131 of the redistribution layers 30 so that the chips 110 are electrically connected to each other. The tiers 10 are singulated to manufacture a plurality of individual fan-out stacked packages 100. The through holes 201 are hemisected to form substantially identical lateral traces 260 on the sidewalls 101 of the fan-out stacked packages 100. Thus, the through holes of the tiers 10 may be formed along the scribe lines.

FIG. 6 is a three-dimensional view of a structure of the fan-out stacked package according to the second embodiment of the present invention. After the singulation process, the lateral traces 260 may be exposed on the sidewalls 101. The lateral traces 260 may be embedded within the recessed areas of the sidewalls 101. The recessed areas are the areas of the tiers 10 wherein the through holes are made to form the lateral traces 260. After singulation, a surface of the lateral traces 260 may be coplanar to the sidewalls 101.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A fan-out stacked package comprising:
a plurality of units stacked on top of each other, each of the plurality of units having sidewalls and comprises:
at least one chip, each of the at least one chip has an active surface and at least one bond pad disposed on the active surface;
an encapsulation encapsulating the at least one chip, the encapsulation having an inner surface and an outer surface of the inner surface;
a redistribution layer disposed on the active surface and the inner surface and electrically connected to the at least one bond pad, the redistribution layer having a trace breakpoint exposed on at least one of the sidewalls; and
a dielectric layer disposed on the redistribution layer; and
at least one adhesive pad disposed on at least one of the plurality of units and configured to attach adjacent units to each other; and
at least one lateral trace formed on at least one of the sidewalls and configured to electrically connect trace breakpoints of the plurality of units.

2. The fan-out stacked package of claim 1, wherein the outer surface of the encapsulation is coplanar to a back surface of the at least one chip.

3. The fan-out stacked package of claim 1, wherein the inner surfaces of the encapsulations are coplanar to the active surface of at least one chip.

4. The fan-out stacked package of claim 1, wherein the encapsulation has a plurality of mold sides configured to encapsulate sidewalls of the at least one chip.

5. The fan-out stacked package of claim 4, wherein widths of the mold sides are different from each other.

6. The fan-out stacked package of claim 4, wherein the mold sides have equal widths.

7. The fan-out stacked package of claim 1, further comprising a plurality of external terminals disposed on a dielectric layer of one of the plurality of units.

8. The fan-out stacked package of claim 1, wherein the at least one lateral trace are disposed on a planar surface of the sidewalls of the plurality of units.

9. The fan-out stacked package of claim 1, wherein the at least one lateral trace are disposed on a recessed area of the sidewalls of the plurality of units.

10. A method of forming a fan-out stacked package, comprising:
forming a plurality of tiers;
stacking the plurality of tiers on top of each other;
performing singulation on the stacked plurality of tiers to form a plurality of units stacked on top of each other, each of the plurality of units being a part of one of the plurality of tiers and having at least one chip, an encapsulation, a redistribution layer, and a dielectric layer; and
forming at least one lateral trace on sidewalls of the plurality of units to electrically connect the redistribution layers, of the plurality of units.

11. The method of claim 10, further comprising:
disposing a plurality of external terminals on a dielectric layer of one of the plurality of units.

12. The method of claim 10, wherein forming the plurality of tiers comprises:
disposing a plurality of chips on a temporary carrier, wherein an active surface of each of the plurality of chips is facing towards the temporary carrier;
forming an encapsulation to encapsulate the plurality of chips, wherein an inner surface of the encapsulation is formed to be coplanar to the active surface of each of the plurality of chips;
grinding the encapsulation to form the outer surface of the encapsulation and expose a back surface of each of the plurality of chips;
decoupling the encapsulation and the plurality of chips from the temporary carrier;
forming a redistribution layer on the active surface of each of the plurality of chips and the inner surface of the encapsulation; and
forming a dielectric layer on the redistribution layer.

13. The method of claim 10, wherein stacking the plurality of tiers on top of each other is stacking the plurality of tiers on top of each other by adhering two adjacent tiers of the plurality of tiers to each other using an adhesive pad.

14. The method of claim 10, wherein forming the at least one lateral trace on the sidewalls of the plurality of units is performed before performing singulation on the stacked plurality of tiers.

15. The method of claim 14, wherein forming the at least one lateral trace on the sidewalls of the plurality of units and performing singulation on the stacked plurality of tiers comprises:
forming through holes along scribe lines of the plurality of tiers, wherein the scribe lines are areas of the plurality of tiers where singulation is performed;
depositing a conductive material within the through holes to form the at least one lateral trace; and
performing singulation along the scribe lines of the stacked plurality of tiers to expose the sidewalls of the plurality of units and the at least one lateral trace embedded in a recessed area of a corresponding sidewall.

16. The method of claim 10, wherein forming the at least one lateral trace on the sidewalls of the plurality of units is performed after performing singulation on the stacked plurality of tiers.

17. The method of claim 16, wherein the at least one lateral trace are disposed on a planar surface of the sidewalls of the plurality of units.

18. The method of claim 10, wherein the encapsulation has a plurality of mold sides formed during singulation to encapsulate sidewalls of the at least one chip of one of the plurality of units.

19. The method of claim 18, wherein widths of the mold sides are different from each other.

20. The method of claim 18, wherein the mold sides have equal widths.
